(19) United States
(12) Patent Application Publication
(10) Pub. No.: US 2009/0140268 A1
(43) Pub. Date: Jun. 4, 2009

(54) LED array module and method of packaging the same

(76) Inventor: Ming-Che Wu, Tsao-Tuen (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/987,430

(22) Filed: Nov. 30, 2007

(51) Int. Cl. H01L 27/15; H01L 33/00

(52) U.S. Cl. 257/88; 438/34; 257/E27.12; 257/E33.001

(57) ABSTRACT

An LED array module includes a drive IC structure, at least one LED array, an adhesive element, and a first conductive structure. The drive IC structure has a concave groove formed on a top side thereof. The at least one LED array is received in the at least one concave groove. The adhesive element is disposed between the at least one LED array and the drive IC structure. The first conductive structure is electrically connected between the drive IC structure and the at least one LED array. Moreover, the LED array module can be disposed on a PCB that has at least one input/output pad. A second conductive structure is electrically connected between the drive IC structure and the at least one input/output pad.

### BACKGROUND OF THE INVENTION

1. Field of the Invention

The present invention relates to an LED array module and a method of packaging the same, and particularly relates to an LED array module and a method of packaging the same via a semiconductor process.

2. Description of the Related Art

In the typical printer technology, a laser is used as a light source in a printer head to scan and transfer the printing information as light signals to a rotating drum in order to generate electrostatic latent images formed on the rotating drum. Moreover, the printing method further includes a toner absorbing step, a transferring step, a hot pressing step, an electrostatic discharging step etc. to achieve printing requirement. However, a laser printer head of the prior art has many optical components, and the mechanism of the laser printer head is complex and the optical path of the laser printer head is very longer. Hence, the optical structure is quite complex and difficult to reduce in size for using a laser in this way. Therefore, the current trend is toward using light emitting diodes to replace lasers as the light sources in printer heads, which can simplify the optical structure.

A further requirement is to reduce the volume of each light emitting diode so as to increase the resolution of the printer. More light emitting diodes may be constructed per unit area in the printer head when the volume of each light emitting diode is reduced. According to the typical packaging method, a highly precise packaging apparatus is required to arrange the light emitting diode arrays and the driver integrated circuits so that they are exactly parallel to each other in a printed circuit board. Then, a wire bonding process is performed to form about 5000 wires between the light emitting diode arrays and the driver integrated circuits if the resolution of the printer is 600 dpi (dots per inch) of A4 size paper. The driver integrated circuits drive the light emitting diode arrays through these wires.

A highly exact and dense wire bonding process in the foregoing method increases the difficulty of the packaging process. This reduces the product yield and indirectly raises the manufacturing cost. Moreover, reducing the volume of the light emitting diodes, although increasing the resolution of the printer, further increases the packaging difficulty.

Therefore, a new package structure and method thereof is required to resolve the foregoing problems.

### SUMMARY OF THE INVENTION

One particular aspect of the present invention is to provide an LED array module and a method of packaging the same. The LED array module is a light exposure module that can be applied to EPG (Electrophotography) printer.

Moreover, the feature of the present invention includes: etching at least one concave groove on the drive IC structure; arranging a light-emitting element array such as an LED array in the at least one concave groove; and then achieving high density electrical connection with 600˜1200 dip via a semiconductor process. Hence, the present invention can reduce product size, material cost, and manufacturing cost due to high density electrical connection.

In order to achieve the above-mentioned aspects, the present invention provides an LED array module including a drive IC structure, at least one LED array, an adhesive element, and a first conductive structure. The drive IC structure has at least one concave groove formed on a top side thereof. The at least one LED array is received in the at least one concave groove. The adhesive element is formed between the at least one LED array and the drive IC structure. The first conductive structure is electrically connected between the drive IC structure and the at least one LED array.

Moreover, the LED array module further includes a PCB that has at least one input/output pad, and the drive IC structure is disposed on the PCB. The LED array module further includes a second conductive structure electrically connected between the drive IC structure and the at least one input/output pad.

In order to achieve the above-mentioned aspects, the present invention provides a method of packaging an LED array module including: forming at least one concave groove on a top side of a drive IC structure; receiving at least one LED array in the at least one concave groove; and forming a first conductive structure that is electrically connected between the drive IC structure and the at least one LED array via a semiconductor process.

Moreover, before receiving the at least one LED array in the at least one concave groove, the method further includes “forming an adhesive element on a lower surface of the at least one LED array” or “forming an adhesive element on a base surface of the at least one concave groove” for making the adhesive element formed between the at least one LED array and the drive IC structure.

Furthermore, the step of forming the first conductive structure further includes: forming a first insulative layer on the drive IC structure and the at least one LED array; patterning the first insulative layer to form a first patterned insulative layer for covering over two width gaps formed between the at least one LED array and the drive IC structure and exposing the drive IC pads and the LED pads; and forming a second insulative layer on the first patterned insulative layer for covering the drive IC pads and the LED pads.

After the step of forming the second insulative layer, the method further includes: patterning the second insulative layer to form a second patterned insulative layer matching with the first patterned insulative layer for exposing the drive IC pads and the LED pads again; forming a plurality of conductive elements, wherein each conductive element is electrically connected between each corresponding drive IC pad and each corresponding LED pad; and removing the second patterned insulative layer and a part of the first patterned insulative layer formed on the at least one LED array to accomplish the LED array module.

In addition, after the step of forming the first conductive structure, the method further includes: arranging the drive IC structure on a PCB that has at least one input/output pad; and forming a second conductive structure electrically connected between the drive IC structure and the at least one input/output pad.

Hence, the present invention utilize the semiconductor process to manufacture a conductive structure for electrically connecting between the at least one LED array and the drive IC structure without using wire-bonding process such as prior art that needs to take a long time. Hence, the present invention not only can reduce product size, material cost, and manufacturing cost, but also increases production speed.

It is to be understood that both the foregoing general description and the following detailed description are exemplary, and are intended to provide further explanation of the invention as claimed. Other advantages and features of the invention will be apparent from the following description, drawings and claims.

### BRIEF DESCRIPTION OF THE DRAWINGS

The various objects and advantages of the present invention will be more readily understood from the following detailed description when read in conjunction with the appended drawings, in which:

FIG. 1 is a flow chart of a method of packaging an LED array module of the present invention;

FIG. 2 is a schematic view of a wafer that has been patterned;

FIG. 3 is an enlarged view of A part of FIG. 2;

FIG. 4 is a cross-sectional view along line 4-4 of FIG. 2; and

FIGS. 5A1 to 5I are cross-sectional, schematic views of a packaging process according to the present invention.

### DETAILED DESCRIPTION OF THE PREFERRED EMBODIMENTS

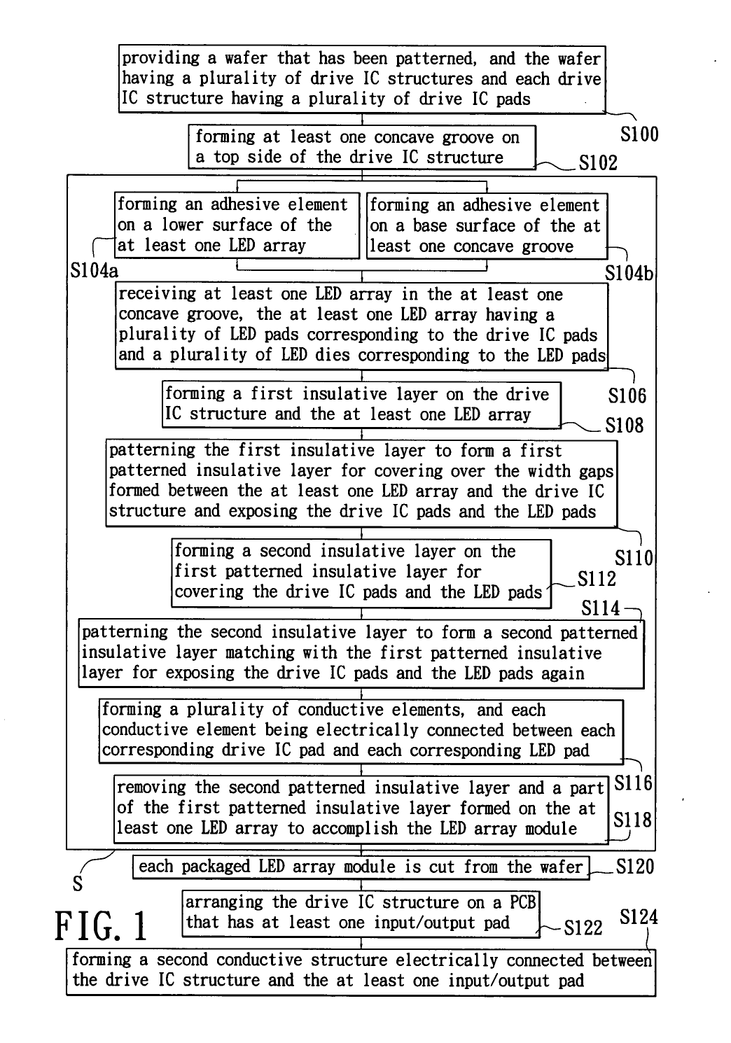

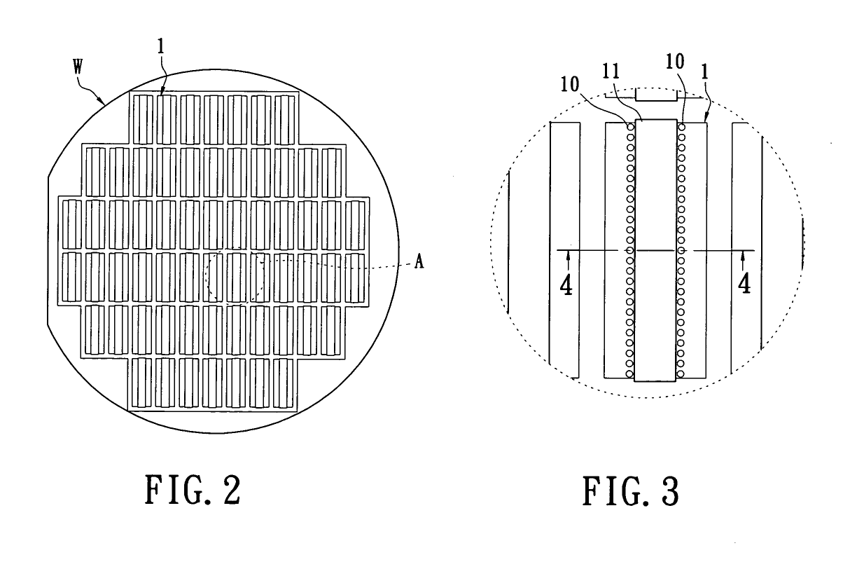

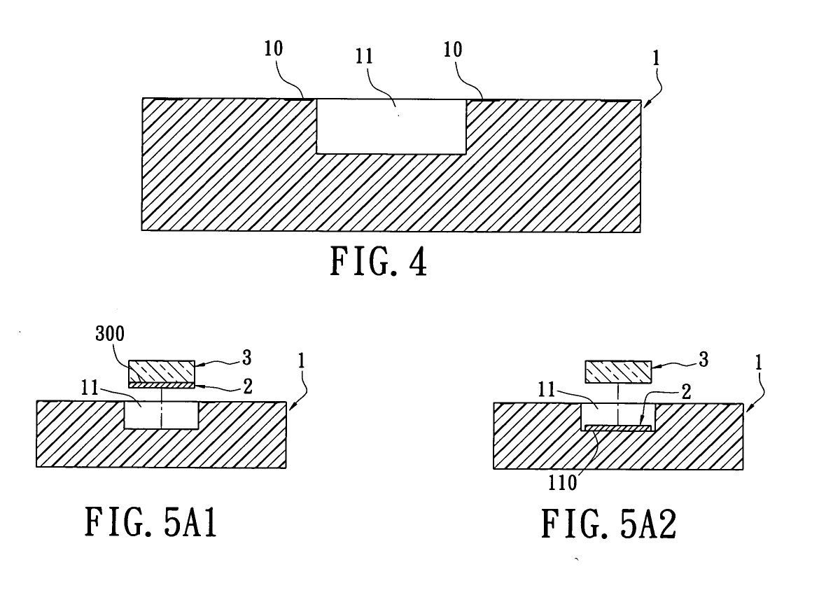

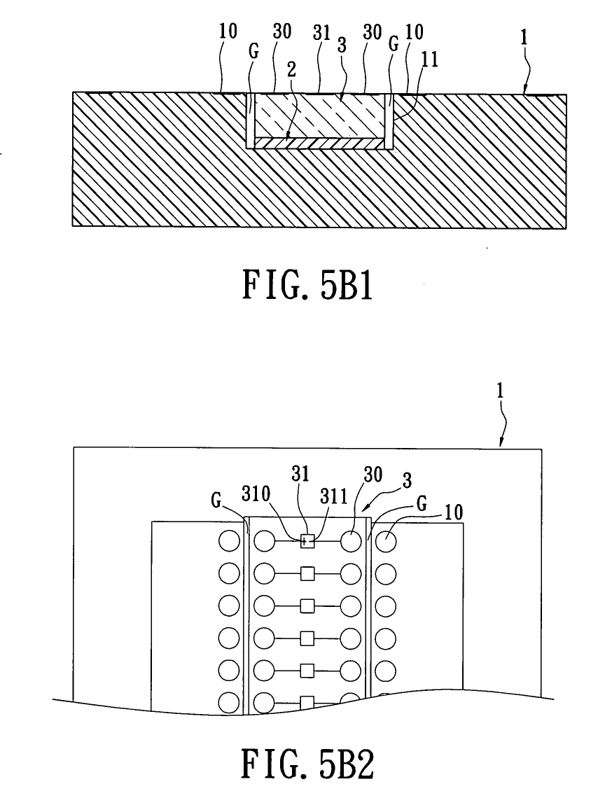

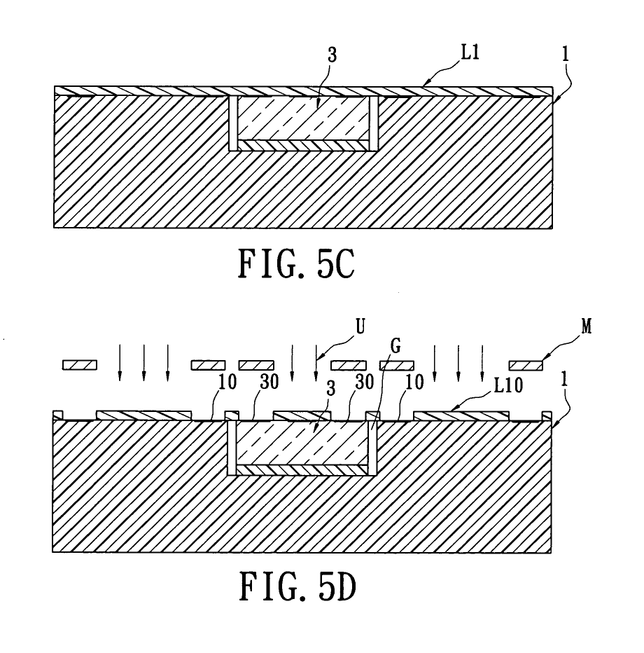

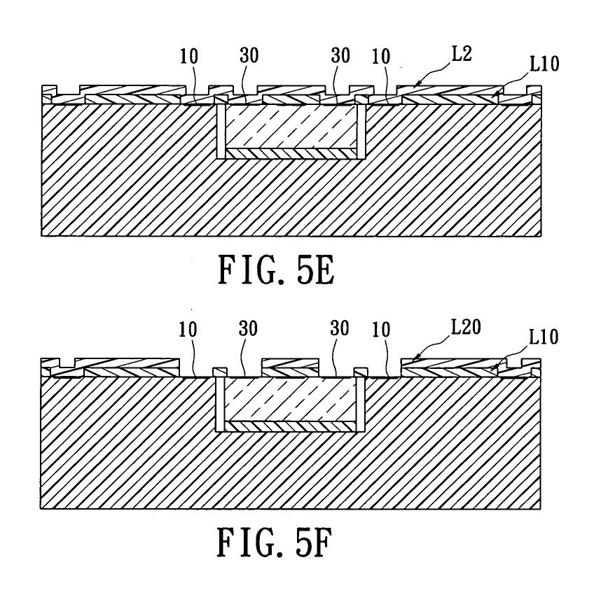

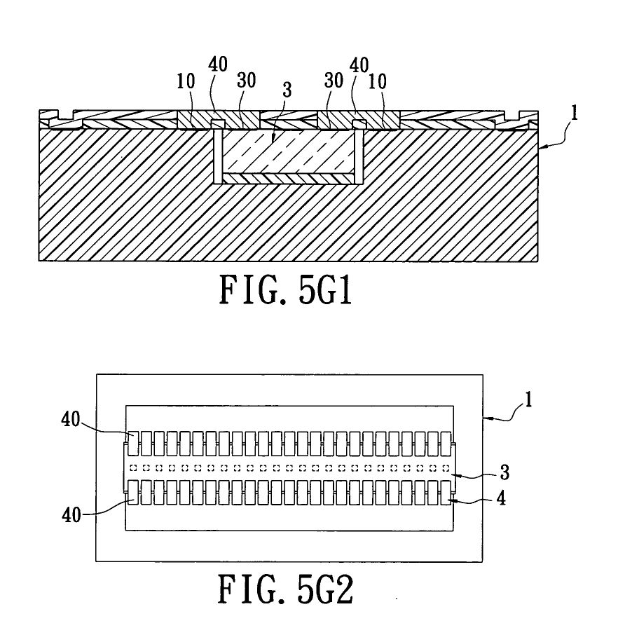

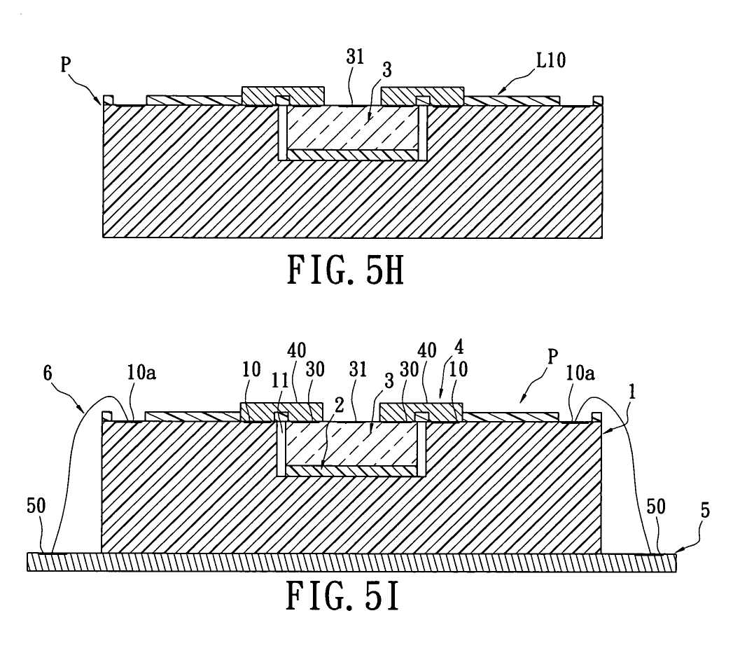

Referring to FIGS. 1 to 4 and 5A1 to 5I, the present invention provides a method of packaging an LED array module. FIG. 1 shows a flow chart of a method of packaging an LED array module of the present invention. FIG. 2 shows a schematic view of a wafer that has been patterned. FIG. 3 shows an enlarged view of A part of FIG. 2. FIG. 4 shows a cross-sectional view along line 4-4 of FIG. 2. FIGS. 5A1 to 5I show cross-sectional, schematic views of a packaging process according to the present invention, respectively.

Referring to FIGS. 1, and 2 to 4 again, the method includes: providing a wafer W that has been patterned, and the wafer having a plurality of drive IC (Integrated Circuit) structures 1 and each drive IC structure 1 having a plurality of drive IC pads 10 (S100); and forming at least one concave groove 11 (that is a receiving space) on a top side of the drive IC structure 1 (S102). The drive IC pads 10 are straightly arranged on the drive IC structure 1. The at least one concave groove 11 is formed on the top side of the drive IC structure 1 via dry etching, wet etching, machining, or any forming method.

Referring to FIGS. 5A1 to 5I again, the step S discloses the manufacturing processes of each drive IC structure. The step S includes the step S104a to step S118.

Referring to FIG. 5A1, forming an adhesive element 2 on a lower surface 300 of the at least one LED array 3 (S104a). Alternatively, referring to FIG. 5A2, forming an adhesive element 2 on a base surface 110 of the at least one concave groove 11 (S104b). The adhesive element 2 can be a silver adhesive, a polymide, or any adhesive colloid.

Referring to FIGS. 5B1 and 5B2 (FIG. 5B1 is a cross-sectional view and FIG. 5B2 is a top view), the method of the present invention further includes: receiving at least one LED array 3 in the at least one concave groove 11, the at least one LED array 3 having a plurality of LED pads 30 corresponding to the drive IC pads 10 and a plurality of LED dies 31 corresponding to the LED pads 30 (S106). Moreover, the adhesive element 2 is arranged between the at least one LED array 3 and the drive IC structure 1.

Furthermore, the LED array module further includes two width gaps G formed between the at least one LED array 3 and the drive IC structure 1. Each width gap G has a width is between 5 and 10 μm. Each width gap G has a height is about 10 μm. In addition, the LED pads 30 are straightly arranged on the at least one LED array 3, that is same as the drive IC pads 10. Each LED die 31 has a positive electrode side 310 and a negative electrode side 311 respectively electrically connected with two corresponding LED pads 30.

Referring to FIG. 5C, the method of the present invention further includes: forming a first insulative layer L1 on the drive IC structure 1 and the at least one LED array 3 (S108). The first insulative layer L1 is a positive photo resist. In other words, the first insulative layer L1 is formed on the drive IC structure 1 and the at least one LED array 3 via a coating process and a pre-cure process.

Referring to FIG. 5D, the method of the present invention further includes: patterning the first insulative layer L1 to form a first patterned insulative layer L10 for covering over the width gaps G formed between the at least one LED array 3 and the drive IC structure 1 and exposing the drive IC pads 10 and the LED pads 30 (S110). In other words, the first patterned insulative layer L10 is formed via using UV light to illuminate the first insulative layer L1 and using a mask M with a predetermined pattern to shade a part of the first insulative layer L1 from the UV light.

Referring to FIG. 5E, the method of the present invention further includes: forming a second insulative layer L2 on the first patterned insulative layer L10 for covering the drive IC pads 10 and the LED pads 30 (S112).

Referring to FIG. 5F, the method of the present invention further includes: patterning the second insulative layer L2 (the process is the same as FIG. 5D) to form a second patterned insulative layer L20 matching with the first patterned insulative layer L10 for exposing the drive IC pads 10 and the LED pads 30 again (S114). Hence, an inverse U-shaped concave groove is formed between each drive IC pad 10 and each LED pad 30 via the matching of the first patterned insulative layer L10 and the second patterned insulative layer L20.

Referring to FIGS. 5G1 and 5G2 (FIG. 5G1 is a cross-sectional view and FIG. 5G2 is a top view), the method of the present invention further includes: forming a plurality of conductive elements 40, and each conductive element 40 being electrically connected between each corresponding drive IC pad 10 and each corresponding LED pad 30 (S116). In other words, a first conductive structure 4 between the drive IC structure 1 and the at least one LED array 3 is composed of the conductive elements 40a that is formed via vapor plating, sputtering, spraying, or coating process.

Referring to FIG. 5H, the method of the present invention further includes: removing the second patterned insulative layer L20 and a part of the first patterned insulative layer L10 formed on the at least one LED array 3 (in order to expose the LED dies 31) to accomplish the LED array module P (S118).

Furthermore, after the step S118, each packaged LED array module P is cut from the wafer W (S120). It means that each drive IC structure 1 is cut from a wafer that has been patterned.

Referring to FIG. 5I, the method of the present invention further includes: arranging the drive IC structure 1 on a PCB 5 that has at least one input/output pad 50 (FIG. 5I shows two input/output pads 50) (S122); and forming a second conductive structure 6 electrically connected between the drive IC structure 1 and the at least one input/output pad 50 (FIG. 5I shows two second conductive structures 6) (S124). The second conductive structure 6 is formed between one power pad 10a of the drive IC structure 1 and the at least one input/output pad 50 (FIG. 5I shows two pairs of power pad 10a and the at least one input/output pad 50) via a wire-bonding process.

Referring to FIG. 5I again, the packaged LED array module P includes a drive IC structure 1, an adhesive element 2, at least one LED array 3, and a first conductive structure 4. The drive IC structure 1 has at least one concave groove 11 and a plurality of drive IC pads 10 formed on a top side thereof. The adhesive element 2 is formed between the at least one LED array 3 and the drive IC structure 1. The at least one LED array 3 is received in the at least one concave groove 11. The at least one LED array 3 has a plurality of LED pads 30 and a plurality of LED dies 31 corresponding to the LED pads 30. The first conductive structure 4 is electrically connected between the drive IC structure 1 and the at least one LED array 3 (Each conductive element 40 is electrically connected between each corresponding drive IC pad 10 and each corresponding LED pad 30).

Moreover, the packaged LED array module P can be arranged on a PCB 5 that has at least one input/output pad 50. A second conductive structure 6 is electrically connected between the power pad 1a and the at least one input/output pad 50.

Furthermore, the drive IC pads 10 can be interlacedly arranged on the drive IC structure 1 and the LED pads 30 can be interlacedly arranged on the at least one LED array 3. Therefore, the LED dies 31 of the at least one LED array 3 can be arranged compactly together.

In conclusion, the LED array module P is a light exposure module that can be applied to EPG (Electrophotography) printer.

Moreover, the feature of the present invention includes: etching at least one concave groove 11 on the drive IC structure 1; arranging a light-emitting element array such as an LED array in the at least one concave groove 11; and then achieving high density electrical connection with 600˜1200 dip via a semiconductor process. Hence, the present invention can reduce product size, material cost, and manufacturing cost due to high density electrical connection.

Hence, the present invention utilize the semiconductor process to manufacture a conductive structure for electrically connecting between the at least one LED array 3 and the drive IC structure 1 without using wire-bonding process such as prior art that needs to take a long time. Hence, the present invention not only can reduce product size, material cost, and manufacturing cost, but also increases production speed.

Although the present invention has been described with reference to the preferred best molds thereof, it will be understood that the invention is not limited to the details thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. An LED array module, comprising:
a drive IC structure having at least one concave groove formed on a top side thereof;
at least one LED array received in the at least one concave groove; and
a first conductive structure electrically connected between the drive IC structure and the at least one LED array.

2. The LED array module as claimed in claim 1, wherein the at least one concave groove is a receiving space formed via etching or machining.

3. The LED array module as claimed in claim 1, further comprising an adhesive element disposed between the at least one LED array and the drive IC structure.

4. The LED array module as claimed in claim 3, wherein the adhesive element is a silver adhesive or a polymide.

5. The LED array module as claimed in claim 1, further comprising two width gaps formed between the at least one LED array and the drive IC structure.

6. The LED array module as claimed in claim 5, wherein each width gap has a width is between 5 and 10 μm.

7. The LED array module as claimed in claim 5, further comprising an insulating layer for covering over the two width gaps.

8. The LED array module as claimed in claim 1, wherein the drive IC structure has a plurality of drive IC pads, and the at least one LED array has a plurality of LED pads corresponding to the drive IC pads.

9. The LED array module as claimed in claim 8, wherein the drive IC pads are straightly arranged on the drive IC structure and the LED pads are straightly arranged on the at least one LED array.

10. The LED array module as claimed in claim 8, wherein the drive IC pads are interlacedly arranged on the drive IC structure and the LED pads are interlacedly arranged on the at least one LED array.

11. The LED array module as claimed in claim 8, wherein the at least one LED array has a plurality of LED dies corresponding to the LED pads, and each LED die has a positive electrode side and a negative electrode side respectively electrically connected with two corresponding LED pads.

12. The LED array module as claimed in claim 8, wherein the first conductive structure has a plurality of conductive elements, and each conductive element is electrically connected between each corresponding drive IC pad and each corresponding LED pad.

13. The LED array module as claimed in claim 1, further comprising a PCB that has at least one input/output pad, wherein the drive IC structure is disposed on the PCB.

14. The LED array module as claimed in claim 13, further comprising a second conductive structure electrically connected between the drive IC structure and the at least one input/output pad.

15. A method of packaging an LED array module, comprising:
forming at least one concave groove on a top side of a drive IC structure;
receiving at least one LED array in the at least one concave groove; and
forming a first conductive structure that is electrically connected between the drive IC structure and the at least one LED array via a semiconductor process.

16. The method as claimed in claim 15, wherein the drive IC structure is cut from a wafer that has been patterned.

17. The method as claimed in claim 15, wherein the at least one concave groove is formed via etching or machining.

18. The method as claimed in claim 15, further comprising forming an adhesive element on a lower surface of the at least one LED array for making the adhesive element formed between the at least one LED array and the drive IC structure, before receiving the at least one LED array in the at least one concave groove.

19. The method as claimed in claim 15, further comprising forming an adhesive element on a base surface of the at least one concave groove for making the adhesive element formed between the at least one LED array and the drive IC structure, before receiving the at least one LED array in the at least one concave groove.

20. The method as claimed in claim 15, wherein the drive IC structure has a plurality of drive IC pads, and the at least one LED array has a plurality of LED pads corresponding to the drive IC pads.

21. The method as claimed in claim 20, wherein the step of forming the first conductive structure further comprises:
forming a first insulative layer on the drive IC structure and the at least one LED array;
patterning the first insulative layer to form a first patterned insulative layer for covering over two width gaps formed between the at least one LED array and the drive IC structure and exposing the drive IC pads and the LED pads;
forming a second insulative layer on the first patterned insulative layer for covering the drive IC pads and the LED pads;
patterning the second insulative layer to form a second patterned insulative layer matching with the first patterned insulative layer for exposing the drive IC pads and the LED pads again;
forming a plurality of conductive elements, wherein each conductive element is electrically connected between each corresponding drive IC pad and each corresponding LED pad; and
removing the second patterned insulative layer and a part of the first patterned insulative layer formed on the at least one LED array to accomplish the LED array module.

22. The method as claimed in claim 15, wherein after the step of forming the first conductive structure, the method further comprising:
arranging the drive IC structure on a PCB that has at least one input/output pad; and
forming a second conductive structure electrically connected between the drive IC structure and the at least one input/output pad.

23. The method as claimed in claim 22, wherein the second conductive structure is formed via a wire-bonding process.
